(19) United States
(12) Patent Application Publication
(10) Pub. No.: US 2010/0248140 A1
(43) Pub. Date: Sep. 30, 2010

(54) LITHOGRAPHIC PRINTING PLATE PRECURSOR AND PLATE MAKING METHOD THEREOF

(76) Inventor: Mamoru Kuramoto, Shizuoka (JP)

Correspondence Address: BIRCH STEWART KOLASCH & BIRCH, PO BOX 747, FALLS CHURCH, VA, 22040-0747, US

(21) Appl. No.: 12/748,821

(22) Filed: Mar. 29, 2010

(30) Foreign Application Priority Data
Mar. 30, 2009 (JP) P2009-083712

(51) Int. Cl. G03F 7/004; G03F 7/20

(52) U.S. Cl. 430/280.1; 430/302

(57) ABSTRACT

A lithographic printing plate precursor includes an aluminum support subjected to a roughening treatment and an image-recording layer containing an infrared absorbing agent, a radical polymerization initiator, a radical polymerizable monomer, a compound having two or more mercapto group-containing groups per molecule and a polymer particle containing a polyalkylene oxide segment.

### FIELD OF THE INVENTION

The present invention relates to a lithographic printing plate precursor and a plate making method using the same. More particularly, it relates to a lithographic printing plate precursor capable of undergoing a direct plate making by image exposure with laser and a plate making method comprising on-press development of the lithographic printing plate precursor.

### BACKGROUND OF THE INVENTION

In general, a lithographic printing plate is composed of an oleophilic image area accepting ink and a hydrophilic non-image area accepting dampening water (fountain solution) in the process of printing. Lithographic printing is a printing method utilizing the nature of water and oily ink to repel with each other and comprising rendering the oleophilic image area of the lithographic printing plate to an ink-receptive area and the hydrophilic non-image area thereof to a dampening water-receptive area (ink-unreceptive area), thereby making a difference in adherence of the ink on the surface of the lithographic printing plate, depositing the ink only to the image area, and then transferring the ink to a printing material, for example, paper.

In order to produce the lithographic printing plate, a lithographic printing plate precursor (PS plate) comprising a hydrophilic support having provided thereon an oleophilic photosensitive resin layer (image-recording layer) is used. Specifically, the PS plate is exposed through a mask, for example, a lith film, and then subjected to development processing, for example, with an alkaline developer to remove the unnecessary image-recording layer corresponding to the non-image area by dissolving while leaving the image-recording layer corresponding to the image area, thereby obtaining the lithographic printing plate.

Due to the recent progress in the technical field, nowadays the lithographic printing plate can be obtained by a CTP (computer-to-plate) technology. Specifically, a lithographic printing plate precursor is directly subjected to scanning exposure using laser or laser diode without using a lith film and developed to obtain a lithographic printing plate.

With the progress described above, the issue on the lithographic printing plate precursor has transferred to improvements, for example, in image-forming property corresponding to the CTP technology, printing property or physical property. Also, with the increasing concern about global environment, as another issue on the lithographic printing plate precursor, an environmental problem on waste liquid discharged accompanying the wet treatment, for example, development processing comes to the front.

In response to the environmental problem, simplification of development or plate making or non-processing has been pursued. As one method of simple plate making, a method referred to as an “on-press development” is practiced. Specifically, according to the method after exposure of a lithographic printing plate precursor, the lithographic printing plate precursor is mounted as it is on a printing machine without conducting conventional development and removal of the unnecessary area of image-recording layer is performed at an early stage of printing step.

Also, as a method of simple development, a method referred to as a “gum development” is practiced wherein the removal of the unnecessary area of image-recording layer is performed using not a conventional high alkaline developer but a finisher or gum solution of near-neutral pH.

In the simplification of plate making operation as described above, a system using a lithographic printing plate precursor capable of being handled in a bright room or under a yellow lump and a light source is preferable from the standpoint of workability. Thus, as the light source, a semiconductor laser emitting an infrared ray having a wavelength of 760 to 1,200 or a solid laser, for example, YAG laser, is used. An UV laser is also used.

As the lithographic printing plate precursor capable of undergoing on-press development, for instance, a lithographic printing plate precursor having provided on a hydrophilic support, an image-recording layer (heat-sensitive layer) containing microcapsules having a radical polymerizable compound encapsulated therein is described in JP-A-2001-277740 (the term “JP-A” as used herein means an “unexamined published Japanese patent application”) and JP-A-2001-277742. A lithographic printing plate precursor having provided on a support, an image-recording layer (photosensitive layer) containing an infrared absorbing agent, a radical polymerization initiator and a radical polymerizable compound is described in JP-A-2002-287334. A lithographic printing plate precursor capable of undergoing on-press development having provided on a support, an image-recording layer containing a radical polymerizable compound and a graft polymer having a polyethylene oxide chain in its side chain or a block polymer having a polyethylene oxide block is described in U.S. Patent Publication No. 2003/0064318.

The methods using the polymerization reaction as described above have the feature that since the chemical bond density in the image area is high, the image strength is relatively good in comparison with the image area formed by the thermal fusion of fine polymer particles. From a practical standpoint, however, on-press development property, printing durability and polymerization efficiency (sensitivity) are still insufficient. According to JP-A-2001-277740 and JP-A-2001-277742, although the printing durability and polymerization efficiency (sensitivity) are increased by providing a protective layer, the on-press development property is degraded. Thus, to achieve compatibility of these properties is difficult.

### SUMMARY OF THE INVENTION

An object of the present invention is to provide a lithographic printing plate precursor capable of being subjected to image recording with laser and achieving compatibility between good on-press development property, printing durability and high sensitivity and a lithographic printing method.

(1) A lithographic printing plate precursor comprising an aluminum support subjected to a roughening treatment and an image-recording layer containing (A) an infrared absorbing agent, (B) a radical polymerization initiator, (C) a radical polymerizable monomer, (D) a compound having two or more mercapto group-containing groups per molecule and (E) a fine polymer particle containing a polyalkylene oxide segment.
(2) The lithographic printing plate precursor as described in (1) above, wherein the mercapto group-containing group is a group represented by formula (a) shown below:

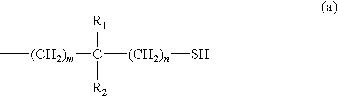

In formula (a), R₁ and R₂ each independently represents a hydrogen atom or an alkyl group having from 1 to 10 carbon atoms, provided that at least one of R₁ and R₂ is an alkyl group, m represents an integer of 0 to 2, and n represents 0 or 1.

(3) The lithographic printing plate precursor as described in (1) or (2) above, wherein the mercapto group-containing group is a group represented by formula (b) shown below:

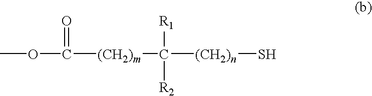

In formula (b), R₁ and R₂ each independently represents a hydrogen atom or an alkyl group having from 1 to 10 carbon atoms, provided that at least one of R₁ and R₂ is an alkyl group, m represents an integer of 0 to 2, and n represents 0 or 1.

(4) The lithographic printing plate precursor as described in anyone of (1) to (3) above, wherein (E) the fine polymer particle is a particle containing a repeating unit having a cyano group.
(5) The lithographic printing plate precursor as described in anyone of (1) to (4) above, wherein (E) the fine polymer particle contains an ethylenically unsaturated bond.
(6) The lithographic printing plate precursor as described in any one of (1) to (5) above, wherein the image-recording layer contains (F) a binder polymer.
(7) The lithographic printing plate precursor as described in (6) above, wherein (F) the binder polymer contains a polyalkylene oxide segment.
(8) The lithographic printing plate precursor as described in (6) or (7) above, wherein (F) the binder polymer contains an ethylenically unsaturated bond.
(9) The lithographic printing plate precursor as described in any one of (1) to (8) above, which has an intermediate layer containing a polymer having both a support-adsorbing group and a polymerizable group between the support and the image-recording layer.
(10) The lithographic printing plate precursor as described in any one of (1) to (9) above, which does not have a protective layer or has a protective layer having a coating amount of 0.7 g/m² or less on the image-recording layer.
(11) The lithographic printing plate precursor as described in (10) above, wherein the protective layer contains an inorganic stratiform compound.
(12) The lithographic printing plate precursor as described in anyone of (1) to (11) above, which contains (G) a borate compound.
(13) The lithographic printing plate precursor as described in (12) above, wherein (G) the borate compound is a compound having a tetraarylborate structure.
(14) A plate making method of the lithographic printing plate precursor as described in any one of (1) to (13) above comprises after imagewise exposure, removing an unexposed area by supplying oily ink and dampening water on a printing machine to prepare a lithographic printing plate without undergoing any development processing step.

The inventor could solve the problem of achieving compatibility between on-press development property, printing durability and sensitivity by using a thiol compound and a fine polymer particle containing a polyalkylene oxide segment.

The mechanism of action of these compounds is not quite clear, but it is believed to be as follows.

In order to achieve the compatibility between on-press development property, printing durability and sensitivity, it is important that a fine polymer particle capable of attaining the on-press development property is firmly crosslinked with a binder polymer or a monomer upon exposure.

Also, the problem of decrease in sensitivity due to oxygen at the exposure is not solved only by providing a protective layer for the purpose of blocking oxygen, because the protective layer raises deterioration of the on-press development property and thus, the compatibility between printing durability and sensitivity is difficult.

However, by incorporating a polyfunctional thiol compound which is not much influenced by an oxygen radical and causes a crosslinking reaction into an image-recording layer, a crosslinking property of the image-recording layer is improved and in addition, when the protective layer is made thinner than an ordinary thickness or even when it is not provided in order to reduce the load of on-press development, increase in the sensitivity has been achieved. Further, improvement in water permeability by providing a polyalkylene oxide group on a surface of fine polymer particle contributes to securement of the on-press development property. It is believed that the polyfunctional thiol compound also contributes to improvement in the on-press development property. It is also believed that when the polyfunctional thiol compound is added to the image-recording layer containing the fine polymer particle containing a polyalkylene oxide segment, due to good mobility of the polyalkylene oxide chain reactivity of the interface of fire particle can be increased, whereby the sensitivity and printing durability can be effectively increased.

It is presumed that due to the combined effect thereof the increase in sensitivity is accomplished and the compatibility between on-press development property, printing durability and sensitivity can be achieved.

According to the present invention, a lithographic printing plate precursor capable of being subjected to image recording with laser and achieving compatibility between good on-press development property, printing durability and high sensitivity and a lithographic printing method can be provided.

### DETAILED DESCRIPTION OF THE INVENTION

### Lithographic Printing Plate Precursor

The lithographic printing plate precursor according to the invention comprises a support and an image-recording layer. The lithographic printing plate precursor may also have a protective layer on the image-recording layer and an intermediate layer between the support and the image-recording layer.

The constituting element, component and the like of the lithographic printing plate precursor according to the invention will be described below.

### (Image-Recording Layer)

The image-recording layer according to the invention contains (A) an infrared absorbing agent, (B) a radical polymerization initiator, (C) a radical polymerizable monomer, (D) a compound having two or more mercapto group-containing groups per molecule and (E) a fine polymer particle containing a polyalkylene oxide segment.

### <(D) Compound Having Two or More Mercapto Group-Containing Groups Per Molecule>

The compound having two or more mercapto group-containing groups per molecule (D) according to the invention is not particularly restricted as long as it is a polyfunctional thiol compound. The mercapto group-containing group is preferably a mercapto group-containing group represented by formula (a) shown below.

Hereinafter, the compound having two or more mercapto group-containing groups per molecule (D) is also referred to as a polyfunctional thiol compound.

### Formula (a):

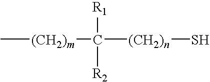

In formula (a), R₁ and R₂ each independently represents a hydrogen atom or an alkyl group having from 1 to 10 carbon atoms, provided that at least one of R₁ and R₂ is an alkyl group, m represents an integer of 0 to 2, and n represents 0 or 1.

In the polyfunctional thiol compound according to the invention, the mercapto group-containing group represented by formula (a) may be connected with any form in the molecule but it is preferably connected in the form of a carboxylic acid derivative represented by formula (b) shown below.

### Formula (b):

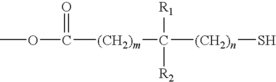

In formula (b), R₁ and R₂ each independently represents a hydrogen atom or an alkyl group having from 1 to 10 carbon atoms, provided that at least one of R₁ and R₂ is an alkyl group, m represents an integer of 0 to 2, and n represents 0 or 1.

In formulae (a) and (b), n is preferably 0. Specifically, the mercapto group-containing group is preferably a secondary or tertiary mercapto group.

Further, the polyfunctional thiol compound preferably has three or more mercapto group-containing groups rather than two mercapto group-containing groups. Two or more mercapto group-containing groups present in the molecule may be the same or different from each other.

In formulae (a) and (b), the alkyl group represented by R₁ or R₂ has preferably from 1 to 5 carbon atoms, more preferably from 1 to 3 carbon atoms, and is most preferably a methyl group.

The structure (residue formed by eliminating the mercapto group-containing groups from the polyfunctional thiol compound) constituting a mother skeleton of the polyfunctional thiol compound according to the invention includes an aliphatic group, an aromatic group, a heterocyclic group and a combination thereof and may have a substituent. Alternatively, it may form a divalent connecting group formed by combination of the above described groups with a connecting group selected from —O—, —S—, —CO—, —NH—, —SO₂— and —SO—.

A number of carbon atoms in the aliphatic group is preferably from 1 to 60, more preferably from 1 to 30, still more preferably from 1 to 20, and most preferably from 1 to 10. The aliphatic group may contain a double bond or a triple bond. The aliphatic group may have a cyclic structure or a branched structure. The aromatic group preferably comprises a benzene ring or a naphthalene ring and more preferably a benzene ring.

The heterocyclic group preferably contains a 3-membered to 10-membered hetero ring, more preferably a 4-membered to 8-membered hetero ring, and most preferably a 5-membered or 6-membered hetero ring. The hetero atom in the hetero ring is preferably a nitrogen atom, an oxygen atom or a sulfur atom. The hetero ring may be condensed or spiro-bonded with an aliphatic ring, an aromatic ring or other hetero ring. Examples of the hetero ring include a pyrrolidine ring, a piperidine ring, a piperazine ring, a morpholine ring, a tetrahydrofuran ring, a tetrahydropyran ring, a tetrahydrothiophene ring, a dioxane ring, an oxazole ring, a thiazole ring, a pyridine ring, a pyrazine ring, a triazine ring, a furan ring, a thiophene ring and an isocyanuric ring. Of the hetero rings, an isocyanuric ring is most preferable. Examples of the substituent for the aliphatic group, aromatic group or heterocyclic group include a hydroxy group, a halogen atom (for example, a chlorine atom), a cyano group, an amino group, a substituted amino group, a heterocyclic group, an acyl group and an acyloxy group. The substituent for the substituted amino group is preferably an alkyl group or an aryl group. The aryl group or heterocyclic group may also have an alkyl group as the substituent.

Specific preferable examples of the mother skeleton of the polyfunctional thiol compound are set forth below, but the invention should not be construed as being limited thereto.

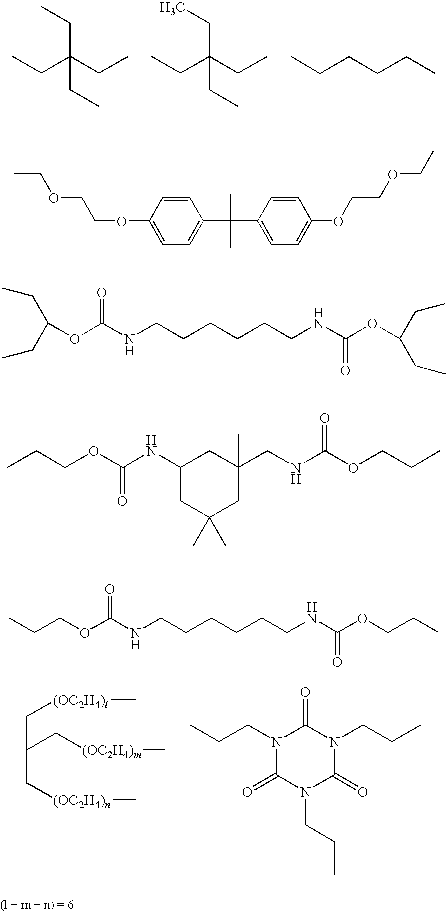

Specific examples of the polyfunctional thiol compound for use in the invention are set forth below, but the invention should not be construed as being limited thereto.

Specifically, compounds having two mercapto groups, for example, 1,2-ethanedithiol, 1,3-propanedithiol, 1,4-butanedithiol, 2,3-butanedithiol, 1,5-pentanedithiol, 1,6-hexanedithol, 1,8-octanedithiol, 1,9-nonanedithiol, 2,3-dimercapto-1-propanol, dithioerythritol, 2,3-dimercaptosuccinic acid, 1,2-benzenedithiol, 1,2-benzenedimethanethiol, 1,3-benzenedithiol, 1,3-benzenedimethanethiol, 1,4-benzenedimethanethiol, 3,4-dimercaptotoluene, 4-chloro-1,3-benzenedithiol, 2,4,6-trimethyl-1,3-benzenedimethanethiol, 4,4′-thiodiphenol, 2-hexylamino-4,6-dimercapto-1,3,5-triazine, 2-diethylamino-4,6-dimercapto-1,3,5-triazine, 2-cyclohexylamino-4,6-dimercapto-1,3,5-triazine, 2-di-n-butylamino-4,6-dimercapto-1,3,5-triazine, ethylene glycol bis(3-mercaptopropionate), butanediol bisthioglycolate, ethylene glycol bisthioglycolate, 2,5-dimercapto-1,3,4-thiadiazole, 2,2′-(ethylenedithio)diethanethiol or 2,2-bis(2-hydroxy-3-mercaptopropoxyphenylpropane), compounds having three mercapto groups, for example, 1,2,6-hexanetrioltrithioglycolate, 1,3,5-trithiocyanuric acid, trimethylolpropane tris(3-mercaptopropionate) or trimethylolpropane tristhioglycolate, and compounds having four or more mercapto groups, for example, pentaerythritol tetrakis(3-mercaptopropionate) or pentaerythritol tetrakisthioglycolate are exemplified. The polyfunctional thiol compound (D) includes commercially available compounds, for example, ethylene glycol bisthiopropionate, trimethylolpropane tristhiopropionate or pentaerythritol tetrakisthiopropionate (each produced by Yodo Kagaku Co., Ltd.)

Of the polyfunctional thiol compounds, since the compound having a large number of the mercapto groups in its molecule exhibits a large improving effect of sensitivity even in a small amount of the addition, the polyfunctional thiol compounds having three or more mercapto groups in the molecules thereof are preferable.

Also, in view of good affinity with the interface of fine polymer particle and the unsaturated monomer, the polyfunctional thiol compound having an ester bond is preferable. The polyfunctional thiol compound having an ester bond preferably includes an ester of thioglycolic acid or 3-mercaptopropionic acid with a polyhydric alcohol.

A molecular weight of the polyfunctional thiol compound according to the invention is not particularly restricted and preferably from 200 to 1,000.

Specific preferable examples of the polyfunctional thiol compound include trimethylolpropane tris(3-mercaptopropionate), pentaerythritol tetrakis(3-mercaptopropionate) and 1,3,5-tris(3-mercaptobutyryloxyethyl)-1,3,5-triazine-2,4,6 (1H,3H,5H)-trione.

The content of the polyfunctional thiol compound in the image-recording layer according to the invention is preferably from 0.1 to 10.0% by weight, more preferably from 0.5 to 5.0% by weight, based on the total solid content of the image-recording layer. Only one kind of the polyfunctional thiol compound may be used or two or more kinds of the polyfunctional thiol compounds may be used as a mixture.

### <Fine Polymer Particle Containing Polyalkylene Oxide Segment>

The image-recording layer according to the invention contains a fine polymer particle containing a polyalkylene oxide segment.

At least one polyalkylene oxide group contained in the fine polymer particle according to the invention means a functional group having at least one polyalkylene oxide group represented by formula —(RO)z- in its molecule. In the formula, z represents an integer of 2 to 200, preferably an integer of 2 to 100. R represents a straight-chain or branched alkylene group having from 1 to 10 carbon atoms, preferably an ethylene group, an n-propylene group or an isopropylene group, and most preferably an ethylene group. At least one polyalkylene oxide group is contained per molecule. Also, two or more of polyalkylene oxide groups or two or more kinds of polyalkylene oxide groups may be contained per molecule.

When R represents an ethylene group, a number average molecular weight (Mn) of the polyethylene oxide segment represented by —(C₂H₄O)z- is preferably from about 500 to about 10,000, more preferably from about 600 to about 8,000, and still more preferably from about 750 to about 4,000.

In the range of Mn described above, since the hydrophilic segment is sufficiently present, the on-press development property is adequately accelerated and ink-receptive property in the image area can be well maintained.

An amount of the polyethylene oxide segment of a graft polymer in the fine polymer particle is preferably from about 0.5 to about 60% by weight, more preferably from about 2 to about 50% by weight, and still more preferably from about 5 to about 40% by weight.

The fine polymer particle containing a polyalkylene oxide segment preferably includes a fine polymer particle having substantially no crosslinking described in U.S. Patent Publication No. 2003/0064318. Also, the fine polymer particle may be a crosslinked polymer particle, that is, an embodiment containing a microgel.

It is preferred that the polyalkylene oxide segment is introduced as a graft chain from the standpoint of on-press development property. The graft chain can be obtained, for example, by copolymerizing a monomer having a radical polymerizable group and a polyalkylene oxide segment with other radical polymerizable monomer. When the other radical polymerizable monomer has one ethylenically unsaturated group, a fine polymer particle having no crosslinking is obtained. When the other radical polymerizable monomer has two or more ethylenically unsaturated groups, a fine polymer particle having crosslinking is obtained.

Alternatively, a microgel is obtained by dispersing a polyfunctional isocyanate in water together with a compound having both at least one of hydroxy group and amino group and a polyalkylene oxide segment to conducting addition polymerization.

The microgel may contain a part of the constituting components of the image-recording layer inside and/or on the surface thereof. In particular, an embodiment of a reactive microgel having (C) a radical polymerizable monomer on the surface thereof is preferable from the standpoint of image-forming sensitivity and printing durability.

Specific examples of the polymer constituting the fine polymer particle include a homopolymer or copolymer of a monomer, for example, ethylene, styrene, divinylbenzene, vinyl chloride, methyl acrylate, ethyl acrylate, methyl methacrylate, ethyl methacrylate, vinylidene chloride, acrylonitrile or vinyl carbazole and a mixture thereof. Among them, a polymer having a skeleton obtained by copolymerization of acrylonitrile, styrene and methyl methacrylate is preferable.

A synthetic method of the fine polymer particle includes a conventional method, for example, an emulsion polymerization method, a soap-free emulsion polymerization method, a seed emulsion polymerization method, a dispersion polymerization method or a suspension polymerization method. From the standpoint of stability of fine polymer particle, an emulsion polymerization method, a soap-free emulsion polymerization method and a seed emulsion polymerization method are preferable, and a polymer latex obtained by a soap-free emulsion polymerization method is particularly preferable.

The polymer latex polymerized by a soap-free emulsion polymerization method includes a polymer latex obtained by emulsion polymerization in the presence of a surfactant having a radical polymerizable unsaturated group in its molecule and a polymer latex in which the polymer partially has a hydrophilic structure in its molecule and the molecular chain per se is molecularly dispersed is preferably used.

In addition, a method (dissolution dispersion method) wherein a polymer is dissolved in a water-insoluble organic solvent, the solution is mixed and emulsified with an aqueous solution containing a dispersant and then the organic solvent is removed by heating to solidify in the form of fine particle is exemplified. As a method for microgelation of the constituting component of the image-recording layer, a known method can be employed.

The fine polymer particle for use in the invention preferably contains as a thermally reactive group, an ethylenically unsaturated bond (for example, an acryloyl group, a methacryloyl group, a vinyl group or an allyl group) capable of undergoing a radical polymerization reaction.

The introduction of the functional group into the fine polymer particle may be conducted at the polymerization or by utilizing a polymer reaction after the polymerization.

In case of introducing at the polymerization, it is preferred to conduct emulsion polymerization or suspension polymerization of a monomer having the functional group. Specific examples of the monomer having the functional group include allyl methacrylate, allyl acrylate, vinyl methacrylate, vinyl acrylate, 2-(vinyloxy)ethyl methacrylate, p-vinyloxystyrene, p-[2-(vinyloxy)ethyl]styrene, a divalent acrylate and a divalent methacrylate, but the invention should not be construed as being limited thereto. The monomer may remain unreacted in the fine polymer particle although it is partially crosslinked.

The average particle size of the fine polymer particle is preferably from 0.01 to 2.0 μm, more preferably from 0.05 to 2.0 μm, particularly preferably from 0.1 to 1.0 μm. In the range described above, good resolution and good time-lapse stability can be achieved.

The content of the fine polymer particle is preferably in a range of 5 to 90% by weight in terms of solid content concentration of the image-recording layer. By the incorporation, strength of the image area can be improved.

### <Infrared Absorbing Agent>

The infrared absorbing agent has a function of converting the infrared ray absorbed to heat and a function of being excited by the infrared ray to perform electron transfer and/or energy transfer to a radical polymerization initiator described hereinafter. The infrared absorbing agent for use in the invention is a dye or pigment having an absorption maximum in a wavelength range of 760 to 1,200 nm.

As the infrared absorbing agent, compounds described in Paragraph Nos. [0058] to [0087] of JP-A-2008-195018 are used.

Of these, cyanine dyes, squarylium dyes, pyrylium dyes and nickel thiolate complexes are preferred infrared absorbing dyes. As the particularly preferable example of the dye, a cyanine dye represented by formula (i) shown below is exemplified.

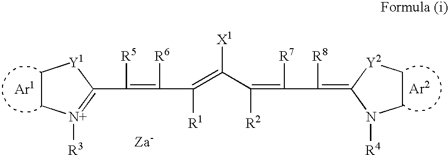

In formula (i), X¹ represents a hydrogen atom, a halogen atom, —N(R⁹)(R¹⁰) X²-L¹ or a group shown below. R⁹ and R¹⁰, which may be the same or different, each represents an aromatic hydrocarbon group having from 6 to 10 carbon atoms, which may have a substituent, an alkyl group having from 1 to 8 carbon atoms, which may have a substituent or a hydrogen atom, or R⁹ and R¹⁰ may be combined with each other to form a ring. Among them, a phenyl group is preferable. X² represents an oxygen atom or a sulfur atom, L¹ represents a hydrocarbon group having from 1 to 12 carbon atoms, an aromatic ring group containing a hetero atom or a hydrocarbon group having from 1 to 12 carbon atoms and containing a hetero atom. The hetero atom used herein indicates a nitrogen atom, a sulfur atom, an oxygen atom, a halogen atom and a selenium atom. In the group shown below, Xa⁻ has the same meaning as Za⁻ defined hereinafter, and R^{a} represents a hydrogen atom or a substituent selected from an alkyl group, an aryl group, a substituted or unsubstituted amino group and a halogen atom.

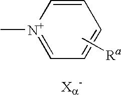

R¹ and R² each independently represents a hydrocarbon group having from 1 to 12 carbon atoms. In view of the preservation stability of a coating solution for image-recording layer, it is preferred that R¹ and R² each represents a hydrocarbon group having two or more carbon atoms. It is also preferred that R¹ and R² are combined with each other to form a 5-membered or 6-membered ring.

Ar¹ and Ar², which may be the same or different, each represents an aromatic hydrocarbon group which may have a substituent. Preferable examples of the aromatic hydrocarbon group include a benzene ring group and a naphthalene ring group. Also, preferable examples of the substituent include a hydrocarbon group having 12 or less carbon atoms, a halogen atom and an alkoxy group having 12 or less carbon atoms. Y¹ and Y², which may be the same or different, each represents a sulfur atom or a dialkylmethylene group having 12 or less carbon atoms. R³ and R⁴, which may be the same or different, each represents a hydrocarbon group having 20 or less carbon atoms, which may have a substituent. Preferable examples of the substituent include an alkoxy group having 12 or less carbon atoms, a carboxyl group and a sulfo group. R⁵, R⁶, R⁷ and R⁸, which may be the same or different, each represents a hydrogen atom or a hydrocarbon group having 12 or less carbon atoms. In view of the availability of raw materials, a hydrogen atom is preferred. Za⁻ represents a counter anion. However, Za⁻ is not necessary when the cyanine dye represented by formula (i) has an anionic substituent in the structure thereof and neutralization of charge is not needed. In view of the preservation stability of a coating solution for image-recording layer, preferable examples of the counter ion for Za⁻ include a halide ion, a perchlorate ion, a tetrafluoroborate ion, a hexafluorophosphate ion and a sulfonate ion, and particularly preferable examples thereof include a perchlorate ion, a hexafluorophosphate ion and an arylsulfonate ion.

Specific examples of the cyanine dye represented by formula (a), which can be preferably used in the invention, include those described in Paragraph Nos. [0017] to [0019] of JP-A-2001-133969, Paragraph Nos. [0012] to [0021] of JP-A-2002-23360 and Paragraph Nos. [0012] to [0037] of JP-A-2002-40638.

The infrared absorbing agents may be used individually or in combination of two or more thereof. In case of using in combination, a pigment may be used. As the pigment, compounds described in Paragraph Nos. [0072] to [0076] of JP-A-2008-195018 are preferably used.

The content of the infrared absorbing agent in the image-recording layer according to the invention is preferably from 0.1 to 10.0% by weight, more preferably from 0.5 to 5.0% by weight, based on the total solid content of the image-recording layer.

### <Radical Polymerization Initiator>

The radical polymerization initiator for use in the invention is a compound generating a radical upon light irradiation.

The radical polymerization initiator preferably used in the invention includes an onium salt, for example, an iodonium salt, a sulfonium salt, a phosphonium salt, a diazonium salt or an azinium salt. Specific examples thereof include compounds described in U.S. Pat. No. 4,708,925, JP-A-7-20629 and JP-A-2008-195018. Also, a benzylsulfonate described in U.S. Pat. Nos. 5,135,838 and 5,200,544 is preferable. Further, an active sulfonate described in JP-A-2-100054, JP-A-2-100055 and JP-A-9-197671, an imido ester, for example, a sulfonate of N-hydroxyimido compound described in JP-A-2008-1740 or a disulfone compound described in JP-A-61-166544 and JP-A-2002-328465 is preferable. Moreover, an oxime ester compound described in J. C. S. Perkin II, 1653-1660 (1979), J. C. S. Perkin II, 156-162 (1979), Journal of Photopolymer Science and Technology, 202-232 (1995), JP-A-2000-66385, JP-A-2000-80068 and JP-A-2008-195018 is preferable. Furthermore, a haloalkyl-substituted s-triazine compound described in JP-A-7-271029 is preferable.

As the radical polymerization initiator, an onium salt, an oxime ester compound, a haloalkyl-substituted s-triazine compound or a disulfone compound is preferable, an onium salt is more preferable, and an iodonium salt, a sulfonium salt or an azinium salt is most preferable.

Specific examples of these compounds are set forth below, but the invention should not be construed as being limited thereto.

Examples of the iodonium salt include diphenyliodonium hexafluorophosphate, 4-methoxyphenyl-4-(2-methylpropyl)phenyliodonium hexafluorophosphate, 4-(2-methylpropyl)phenyl-p-tolyliodonium hexafluorophosphate, 4-hexyloxyphenyl-2,4,6-trimethoxyphenyliodonium hexafluorophosphate, 4-hexyloxyphenyl-2,4-diethoxyphenyliodoniumtetraphenylborate, 4-octyloxyphenyl-2,4,6-trimethoxyphenyliodonium 1-perfluorobutanesulfonate and 4-octyloxyphenyl-2,4,6-trimethoxyphenyliodonium hexafluorophosphate.

Examples of the sulfonium salt include triphenylsulfonium hexafluorophosphate, triphenylsulfonium benzoylformate, bis(4-chlorophenyl)phenylsulfonium benzoylformate, bis(4-chlorophenyl)-4-methylphenylsulfonium tetrafluoroborate and tris(4-chlorophenyl)sulfonium 3,5-bis(methoxycarbonyl)benzenesulfonate.

Examples of the azinium salt include 1-cyclohexylmethyloxypyridinium hexafluorophosphate, 1-cyclohexyloxy-4-phenylpyridinium hexafluorophosphate, 1-ethoxy-4-phenylpyridinium hexafluorophosphate, 1-(2-ethylhexyloxy)-4-phenylpyridinium hexafluorophosphate, 4-chloro-1-cyclohexylmethyloxypyridinium hexafluorophosphate, 1-ethoxy-4-cyanopyridinium hexafluorophosphate, 3,4-dichloro-1-(2-ethylhexyloxy)pyridinium hexafluorophosphate, 1-benzyloxy-4-phenylpyridinium hexafluorophosphate, 1-phenethyloxy-4-phenylpyridinium hexafluorophosphate, 1-(2-ethylhexyloxy)-4-phenylpyridinium p-toluenesulfonate, 1-(2-ethylhexyloxy)-4-phenylpyridinium perfluorobutanesulfonate, 1-(2-ethylhexyloxy)-4-phenylpyridinium bromide and 1-(2-ethylhexyloxy)-4-phenylpyridinium tetrafluoroborate.

The radical polymerization initiator can be added to the image-recording layer preferably in an amount from 0.1 to 50% by weight, more preferably from 0.5 to 30% by weight, particularly preferably from 0.8 to 20% by weight, based on the total solid content constituting the image-recording layer. In the range described above, good color image is obtained.

### <Radical Polymerizable Monomer>

The radical polymerizable monomer for use in the invention is an addition-polymerizable compound having at least one ethylenically unsaturated double bond, and it is preferably selected from compounds having at least one, preferably two or more, terminal ethylenically unsaturated double bonds. Such compounds are widely known in the field of art and they can be used in the invention without any particular limitation. The compound has a chemical form, for example, a monomer, a prepolymer, specifically, a dimer, a trimer or an oligomer, or a (co)polymer thereof, or a mixture thereof.

Specific examples of the radical polymerizable compound include compounds described in Paragraph Nos. [0089] to [0098] of JP-A-2008-195018. Among them, esters of aliphatic polyhydric alcohol compound with an unsaturated carboxylic acid (for example, acrylic acid, methacrylic acid, itaconic acid, crotonic acid, isocrotonic acid or maleic acid) are preferably exemplified. Other preferable radical polymerizable monomer includes radical polymerizable monomers containing an isocyanuric acid structure described in JP-A-2005-329708.

Among them, isocyanuric acid ethylene oxide-modified acrylates, for example, tris(acryloyloxyethyl)isocyanurate or bis(acryloyloxyethyl)hydroxyethyl isocyanurate are particularly preferable.

The radical polymerizable monomer is preferably used in an amount from 5 to 80% by weight, more preferably from 25 to 75% by weight, based on the total solid content of the image-recording layer.

### <Other Components>

The image-recording layer according to the invention may further contain other components, if desired.

### (1) Borate Compound

The image-recording layer according to the invention preferably contains a borate compound. By using the borate compound, the sensitivity is further increased.

As the borate compound for use in the invention, a compound having a borate anion structure may be used without particular restriction and a borate compound having a structure represented by formula (I) shown below is preferable.

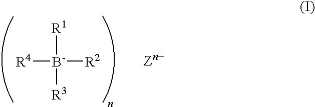

In formula (I), R¹ to R⁴ each independently represents a monovalent organic group, Zⁿ⁺ represents an n-valent cation, and n represents an integer of 1 to 6.

The monovalent organic group represented by any one of R¹ to R⁴ includes an alkyl group, an alkenyl group, an aryl group, an alkynyl group and a cycloalkyl group and is preferably an aryl group. The monovalent organic group may have a substituent. Examples of the substituent which may be introduced include an alkyl group, an alkenyl group, an alkynyl group, an aryl group, a halogen atom, an alkoxy group, an alkoxycarbonyl group, an amino group, a cyano group, an amido group, a urethane group, a sulfo group, a thioalkoxy group and a carboxyl group.

The compound wherein R¹ to R⁴ each represents an aryl group is preferable. The aryl group having as a substituent, an electron attracting group is more preferable. R¹ to R⁴ may be the same or different. As the electron attracting group introduced into the aryl group, a halogen atom or a fluoroalkyl group is preferable, and a fluorine atom or a trifluoromethyl group is more preferable.

Zⁿ⁺ preferably represents an alkali metal cation or a quaternary ammonium cation, and more preferably a tetraalkylammonium cation.

The content of the borate compound in the image-recording layer according to the invention is preferably from 0.1 to 20% by weight, more preferably from 1 to 10% by weight, in terms of solid content in view of film-forming property.

### (2) Binder Polymer

In the image-recording layer according to the invention, a binder polymer can be used for the purpose of improving film strength of the image-recording layer. The binder polymer which can be used in the invention can be selected from those heretofore known without restriction, and polymers having a film-forming property are preferable. Among them, acrylic resins, polyvinyl acetal resins and polyurethane resins are preferable.

As the binder polymer preferable for the invention, a polymer having a crosslinkable functional group for improving film strength of the image area in its main chain or side chain, preferably in its side chain, as described in JP-A-2008-195018 is exemplified. Due to the crosslinkable functional group, crosslinkage is formed between the polymer molecules to facilitate curing.

As the crosslinkable functional group, an ethylenically unsaturated group, for example, a (meth) acryl group, a vinyl group or an allyl group or an epoxy group is preferable. The crosslinkable functional group can be introduced into the polymer by a polymer reaction or copolymerization. For instance, a reaction between an acrylic polymer or polyurethane having a carboxyl group in its side chain and glycidyl methacrylate or a reaction between a polymer having an epoxy group and a carboxylic acid containing an ethylenically unsaturated group, for example, methacrylic acid can be utilized.

The content of the crosslinkable group in the binder polymer is preferably from 0.1 to 10.0 mmol, more preferably from 1.0 to 7.0 mmol, most preferably from 2.0 to 5.5 mmol, based on 1 g of the binder polymer.

It is also preferred that the binder polymer for use in the invention further contains a hydrophilic group. The hydrophilic group contributes to impart the on-press development property to the image-recording layer. In particular, coexistence of the crosslinkable group and the hydrophilic group makes it possible to maintain good balance between printing durability and developing property.

The hydrophilic group includes, for example, a hydroxy group, a carboxyl group, an alkylene oxide structure, an amino group, an ammonium group, an amido group, a sulfo group and a phosphoric acid group. Among them, an alkylene oxide structure containing from 1 to 9 alkylene oxide units having 2 or 3 carbon atoms is preferable. In order to introduce a hydrophilic group into the binder polymer, a monomer having the hydrophilic group is copolymerized.

In order to control the ink-receptive property, an oleophilic group, for example, an alkyl group, an aryl group, an aralkyl group or an alkenyl group may be introduced into the binder polymer according to the invention. Specifically, an oleophilic group-containing monomer, for example, an alkyl methacrylate is copolymerized.

Specific examples (1) to (11) of the binder polymer for use in the invention are set forth below, but the invention should not be construed as being limited thereto.

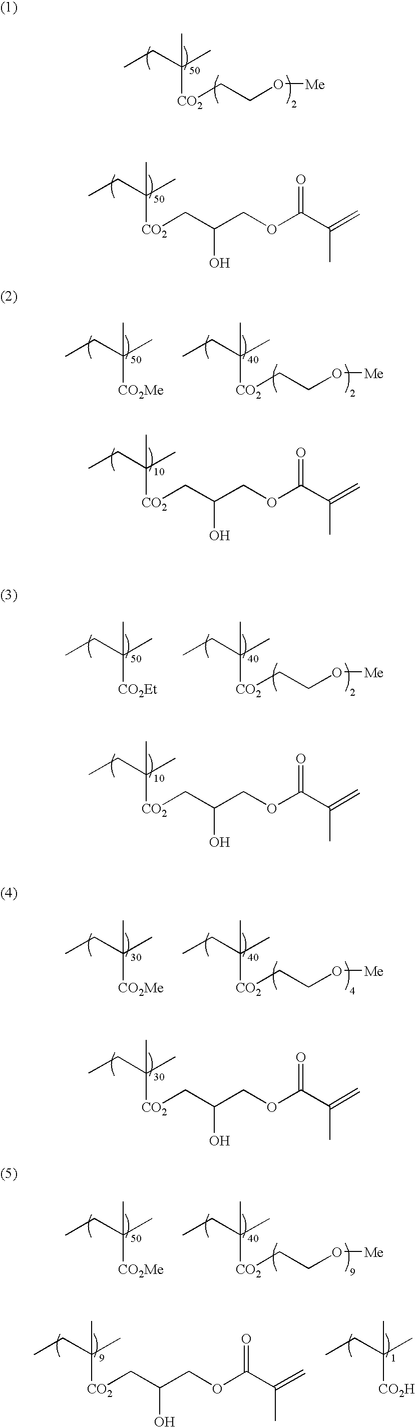

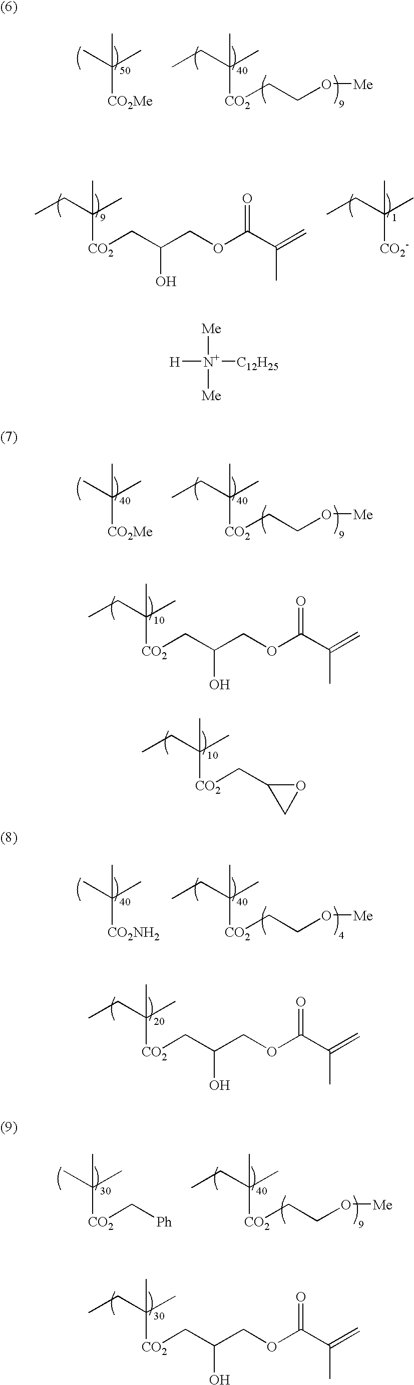

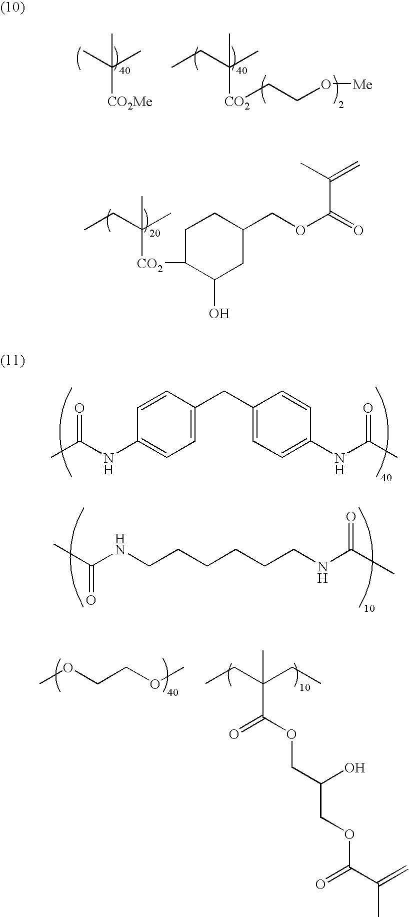

The weight average molecular weight (Mw) of the binder polymer according to the invention is preferably 2,000 or more, more preferably 5,000 or more, and still more preferably from 10,000 to 300,000.

According to the invention, a hydrophilic polymer, for example, polyacrylic acid or polyvinyl alcohol described in JP-A-2008-195018 may be used, if desired. Further, an oleophilic binder polymer is used together with a hydrophilic binder polymer.

The content of the binder polymer is preferably from 5 to 90% by weight, more preferably from 5 to 80% by weight, further more preferably from 10 to 70% by weight, based on the total solid content of the image-recording layer.

### (3) Hydrophilic Low Molecular Weight Compound

The image-recording layer according to the invention may contain a hydrophilic low molecular weight compound in order to improve the on-press development property without accompanying the decrease in the printing durability.

The hydrophilic low molecular weight compound includes a water-soluble organic compound, for example, a glycol compound, e.g., ethylene glycol, diethylene glycol, triethylene glycol, propylene glycol, dipropylene glycol or tripropylene glycol, or an ether or ester derivative thereof, a polyhydroxy compound, e.g., glycerine, pentaerythritol or tris(2-hydroxyethyl)isocyanurate, an organic amine compound, e.g., triethanol amine, diethanol amine or monoethanol amine, or a salt thereof, an organic sulfonic acid compound, e.g., an alkyl sulfonic acid, toluene sulfonic acid or benzene sulfonic acid, or a salt thereof, an organic sulfamic acid compound, e.g., an alkyl sulfamic acid, or a salt thereof, an organic sulfuric acid compound, e.g., an alkyl sulfuric acid or an alkyl ether sulfuric acid, or a salt thereof, an organic phosphonic acid compound, e.g., phenyl phosphonic acid, or a salt thereof, an organic carboxylic acid, e.g., tartaric acid, oxalic acid, citric acid, malic acid, lactic acid, gluconic acid or an amino acid, or a salt thereof and a betaine compound.

According to the invention, it is preferred that at least one compound selected from a polyol compound, an organic sulfate compound, an organic sulfonate compound and a betaine compound is incorporated.

Specific examples of the organic sulfonate compound include an alkylsulfonate, for example, sodium n-butylsulfonate, sodium n-hexylsulfonate, sodium 2-ethylhexylsulfonate, sodium cyclohexylsulfonate or sodium n-octylsulfonate; an alkylsulfonate containing an ethylene oxide chain, for example, sodium 5,8,11-trioxapentadecane-1-sulfate, sodium 5,8,11-trioxaheptadecane-1-sulfate, sodium 13-ethyl-5,8,11-trioxaheptadecane-1-sulfate or sodium 5,8,11,14-tetraoxatetracosane-1-sulfate; and an arylsulfonate, for example, sodium benzenesulfonate, sodium p-toluenesulfonate, sodium p-hydroxybenzenesulfonate, sodium p-styrenesulfonate, sodium isophthalic acid dimethyl-5-sulfonate, sodium 1-naphtylsulfonate, sodium 4-hydroxynaphtylsulfonate, disodium 1,5-naphtyldisulfonate or trisodium 1,3,6-naphtyltrisulfonate. The salt may also be potassium salt or lithium salt.

The organic sulfate compound includes a sulfate of alkyl, alkenyl, alkynyl, aryl or heterocyclic monoether of polyethylene oxide. The number of unit of ethylene oxide is preferably from 1 to 4. The salt is preferably a sodium salt, a potassium salt or a lithium salt.

As the betaine compound, a compound wherein a number of carbon atoms included in a hydrocarbon substituent on the nitrogen atom is from 1 to 5 is preferable. Specific examples thereof include trimethylammonium acetate, dimethylpropylammonium acetate, 3-hydroxy-4-trimethylammoniobutyrate, 4-(1-pyridinio)butyrate, 1-hydroxyethyl-1-imidazolioacetate, trimethylammonium methanesulfonate, dimethylpropylammonium methanesulfonate, 3-trimethylammonio-1-porpanesulfonate and 3-(1-pyridinio)-1-porpanesulfonate.

Since the hydrophilic low molecular weight compound has a small structure of hydrophobic portion and almost no surface active function, degradations of the hydrophobicity and film strength in the image area due to penetration of dampening water into the exposed area (image area) of the image-recording layer are prevented and thus, the ink receptive-property and printing durability of the image-recording layer can be preferably maintained.

The amount of the hydrophilic low molecular weight compound added to the image-recording layer is preferably from 0.5 to 20% by weight, more preferably from 1 to 10% by weight, still more preferably from 2 to 8% by weight, based on the total solid content of the image-recording layer. In the range described above, good on-press development property and good printing durability are achieved.

The hydrophilic low molecular weight compounds may be used individually or as a mixture of two or more thereof.

### (4) Oil-Sensitizing Agent

In order to improve the ink-receptive property, an oil-sensitizing agent, for example, a phosphonium compound, a nitrogen-containing low molecular weight compound or an ammonium group-containing polymer can be used in the image-recording layer. In particular, in the case where an inorganic stratiform compound is incorporated into a protective layer described hereinafter, the oil-sensitizing agent functions as a surface covering agent of the inorganic stratiform compound and prevents deterioration of the ink-receptive property during printing due to the inorganic stratiform compound.

As preferable examples of the phosphonium compound, phosphonium compounds described in JP-A-2006-297907 and JP-A-2007-50660 are exemplified. Specific examples of the phosphonium compound include tetrabutylphosphonium iodide, butyltriphenylphosphonium bromide, tetraphenylphosphonium bromide, 1,4-bis(triphenylphosphonio)butane di(hexafluorophosphate), 1,7-bis(triphenylphosphonio)heptane sulfate and 1,9-bis(triphenylphosphonio)nonane naphthalene-2,7-disulfonate.

As the nitrogen-containing low molecular weight compound, an amine salt and a quaternary ammonium salt are exemplified. Also, an imidazolinium salt, a benzimidazolinium salt, a pyridinium salt and a quinolinium salt are exemplified. Of the nitrogen-containing low molecular weight compounds, the quaternary ammonium salt and pyridinium salt are preferably used. Specific examples the nitrogen-containing low molecular weight compound include tetramethylammonium hexafluorophosphate, tetrabutylammonium hexafluorophosphate, dodecyltrimethylammonium p-toluenesulfonate, benzyltriethylammonium hexafluorophosphate, benzyldimethyloctylammonium hexafluorophosphate and benzyldimethyldodecylammonium hexafluorophosphate.

The ammonium group-containing polymer may be any polymer containing an ammonium group in its structure and is preferably a polymer containing from 5 to 80% by mole of (meth)acrylate having an ammonium group in its side chain as a copolymerization component.

As to the ammonium group-containing polymer, its reduced specific viscosity value (unit: cSt/g/ml) determined according to the measuring method described below is preferably from 5 to 120, more preferably from 10 to 110, particularly preferably from 15 to 100.

### <Measuring Method of Reduced Specific Viscosity>

In a 20 ml measuring flask was weighed 3.33 g of a 30% polymer solution (1 g as a solid content) and the measuring flask was filled up to the gauge line with N-methylpyrrolidone. The resulting solution was put into an Ubbelohde viscometer (viscometer constant: 0.010 cSt/s) and a period for running down of the solution at 30° C. was measured. The viscosity was determined in a conventional manner according to the following calculating formula:

Kinetic viscosity=Viscometer constant×Period for liquid to pass through a capillary (sec)

Specific examples of the ammonium group-containing polymer are set forth below.

(1) 2-(Trimethylammonio)ethyl methacrylate p-toluenesulfonate/3,6-dioxaheptyl methacrylate copolymer (molar ratio: 10/90)
(2) 2-(Trimethylammonio)ethyl methacrylate hexafluorophosphate/3,6-dioxaheptyl methacrylate copolymer (molar ratio: 20/80)
(3) 2-(Ethyldimethylammonio)ethyl methacrylate p-toluenesulfonate/hexyl methacrylate copolymer (molar ratio: 30/70)
(4) 2-(Trimethylammonio)ethyl methacrylate hexafluorophosphate/2-ethylhexyl methacrylate copolymer (molar ratio: 20/80)
(5) 2-(Trimethylammonio)ethyl methacrylate methylsulfate/hexyl methacrylate copolymer (molar ratio: 40/60)
(6) 2-(Butyldimethylammonio)ethyl methacrylate hexafluorophosphate/3,6-dioxaheptyl methacrylate copolymer (molar ratio: 20/80)
(7) 2-(Butyldimethylammonio)ethyl acrylate hexafluorophosphate/3,6-dioxaheptyl methacrylate copolymer (molar ratio: 20/80)
(8) 2-(Butyldimethylammonio)ethyl methacrylate 13-ethyl-5,8,11-trioxa-1-heptadecanesulfonate/3,6-dioxaheptyl methacrylate copolymer (molar ratio: 20/80)
(9) 2-(Butyldimethylammonio) ethyl methacrylate hexafluorophosphate/3,6-dioxaheptyl methacrylate/2-hydroxy-3-methacryloyloxypropyl methacrylate copolymer (molar ratio: 15/80/5)

The content of the oil-sensitizing agent is preferably from 0.01 to 30.0% by weight, more preferably from 0.1 to 15.0% by weight, still more preferably from 1 to 5% by weight, based on the total solid content of the image-recording layer.

### (5) Other Components

Other components, for example, a surfactant, a coloring agent, a print-out agent, a polymerization inhibitor, a higher fatty acid derivative, a plasticizer, a fine inorganic particle, an inorganic stratiform compound, a co-sensitizer or a chain transfer agent may further be added to the image-recording layer. Specifically, compounds and amounts added thereof described, for example, in Paragraph Nos. [0114] to [0159] of JP-A-2008-284817, Paragraph Nos. [0023] to [0027] of JP-A-2006-91479 and Paragraph No. [0060] of U.S. Patent Publication No. 2008/0311520 are preferably used.

### [Formation of Image-Recording Layer]

The image-recording layer according to the invention is formed by dispersing or dissolving each of the necessary constituting components described above in a solvent to prepare a coating solution and coating the solution on a support by a known method, for example, bar coater coating and drying as described in Paragraph Nos. [0142] to [0143] of JP-A-2008-195018. The coating amount (solid content) of the image-recording layer formed on a support after coating and drying may be varied according to the intended purpose but is in general preferably from 0.3 to 3.0 g/m². In the range described above, good sensitivity and good film property of the image-recording layer can be achieved.

### (Intermediate Layer)

In the lithographic printing plate precursor according to the invention, an intermediate layer (also referred to as an undercoat layer) is preferably provided between the image-recording layer and the support. The intermediate layer strengthens adhesion between the support and the image-recording layer in the exposed area and makes removal of the image-recording layer from the support in the unexposed area easy, thereby contributing improvement in the developing property without accompanying degradation of the printing durability. Further, it is advantageous that in the case of infrared laser exposure, since the intermediate layer acts as a heat insulating layer, decrease in sensitivity due to diffusion of heat generated upon the exposure into the support is prevented.

As a compound for use in the intermediate layer, specifically, for example, a silane coupling agent having an addition-polymerizable ethylenic double bond reactive group described in JP-A-10-282679 and a phosphorus compound having an ethylenic double bond reactive group described in JP-A-2-304441 are preferably exemplified. A polymer resin having an adsorbing group capable of adsorbing to a surface of the support, a hydrophilic group and a crosslinkable group as described in JP-A-2005-125749 and JP-A-2006-188038 is more preferably exemplified. The polymer resin is preferably a copolymer of a monomer having an adsorbing group, a monomer having a hydrophilic group and a monomer having a crosslinkable group. More specifically, a polymer resin which is a copolymer of a monomer having an adsorbing group, for example, a phenolic hydroxy group, a carboxyl group, —PO₃H₂, —OPO₃H₂, —CONHSO₂—, —SO₂NHSO₂— and —COCH₂COCH₃, a monomer having a hydrophilic sulfo group and a monomer having a polymerizable crosslinkable group, for example, a methacryl group or an allyl group. The polymer resin may contain a crosslinkable group introduced by a salt formation between a polar substituent of the polymer resin and a compound containing a substituent having a counter charge to the polar substituent of the polymer resin and an ethylenically unsaturated bond and also may be further copolymerized with a monomer other than those described above, preferably a hydrophilic monomer.

The content of the unsaturated double bond in the polymer resin for intermediate layer is preferably from 0.1 to 10.0 mmol, most preferably from 2.0 to 5.5 mmol, based on 1 g of the polymer resin.

The weight average molecular weight (Mw) of the polymer resin for intermediate layer is preferably 5,000 or more, more preferably from 10,000 to 300,000.

The intermediate layer according to the invention may contain a chelating agent, a secondary or tertiary amine, a polymerization inhibitor or a compound containing an amino group or a functional group having polymerization inhibition ability and a group capable of interacting with the surface of aluminum support (for example, 1,4-diazobicyclo[2,2,2]octane (DABCO), 2,3,5,6-tetrahydroxy-p-quinone, chloranil, sulfophthalic acid, hydroxyethylenediaminetriacetic acid, dihydroxyethylenediaminediacetic acid or hydroxyethyliminodiacetic acid) in addition to the compounds for the intermediate layer described above in order to prevent the occurrence of stain due to preservation of the lithographic printing plate precursor.

The intermediate layer is coated according to a known method. The coating amount (solid content) of the intermediate layer is preferably from 0.1 to 100 mg/m², and more preferably from 1 to 30 mg/m².

### (Support)

As the support for use in the invention, an aluminum support subjected to a roughening treatment is used. Particularly, an aluminum plate subjected to roughening treatment and anodizing treatment according to a known method is preferable.

Also, other treatments, for example, an enlarging treatment or a sealing treatment of micropores of the anodized film described in JP-A-2001-253181 and JP-A-2001-322365 or a surface hydrophilizing treatment, for example, with an alkali metal silicate as described in U.S. Pat. Nos. 2,714,066, 3,181,461, 3,280,734 and 3,902,734 or polyvinyl phosphonic acid as described in U.S. Pat. Nos. 3,276,868, 4,153,461 and 4,689,272 may be appropriately selected and applied to the aluminum plate, if desired.

The support preferably has a center line average roughness of 0.10 to 1.2 μm.

The support may have a backcoat layer containing an organic polymer compound described in JP-A-5-45885 or an alkoxy compound of silicon described in JP-A-6-35174, provided on the back surface thereof, if desired.

### (Protective Layer)

In the lithographic printing plate precursor according to the invention, an embodiment wherein a protective layer is not provided on the image-recording layer is included, but a protective layer (overcoat layer) may be provided, if desired. The protective layer has a function for preventing, for example, occurrence of scratch in the image-recording layer or ablation caused by exposure with a high illuminance laser beam, in addition to the function for restraining an inhibition reaction against the image formation by means of oxygen blocking.

With respect to the protective layer having such properties, there are described, for example, in U.S. Pat. No. 3,458,311 and JP-B-55-49729 (the term “JP-B” as used herein means an “examined Japanese patent publication”). As a polymer having low oxygen permeability for use in the protective layer, any water-soluble polymer and water-insoluble polymer can be appropriately selected to use. Specifically, for example, polyvinyl alcohol, a modified polyvinyl alcohol, polyvinyl pyrrolidone, a water-soluble cellulose derivative and poly(meth)acrylonitrile are exemplified.

It is preferred that the protective layer contains an inorganic stratiform compound, that is, an inorganic compound having a stratiform structure and a tabular shape. By the incorporation of inorganic stratiform compound into the protective layer, the oxygen-blocking property is further increased, film strength of the protective layer is further increased to increase the scratch resistance, and a matting property can be provided to the protective layer.

The stratiform compound includes, for instance, mica, for example, natural mica represented by the following formula: A (B,C)₂₋₅D₄O₁₀(OH,F,O)₂, (wherein A represents any one of Li, K, Na, Ca, Mg and an organic cation, B and C each represents any one of Fe (II), Fe(III), Mn, Al, Mg and V, and D represents Si or Al) or synthetic mica, talc represented by the following formula: 3MgO.4SiO.H₂O, teniolite, montmorillonite, saponite, hectolite and zirconium phosphate.

Of the mica compounds, examples of the natural mica include muscovite, paragonite, phlogopite, biotite and lepidolite. Examples of the synthetic mica include non-swellable mica, for example, fluorphlogopite KMg₃(AlSi₃O₁₀)F₂ or potassium tetrasilic mica KMg_{2.5}(Si₄O₁₀)F₂, and swellable mica, for example, Na tetrasilic mica NaMg_{2.5}(Si₄O₁₀)F₂, Na or Li teniolite (Na,Li)Mg₂Li(Si₄O₁₀)F₂, or montmorillonite based Na or Li hectolite (Na,Li)_{1/8}Mg_{2/5}Li_{1/8}(Si₄O₁₀)F₂. Synthetic smectite is also useful.

Of the mica compounds, fluorine-based swellable mica, which is a synthetic stratiform compound, is particularly useful in the invention. Specifically, the swellable synthetic mica and an swellable clay mineral, for example, montmorillonite, saponite, hectolite or bentonite have a stratiform structure comprising a unit crystal lattice layer having thickness of approximately 10 to 15 angstroms, and metallic atom substitution in the lattices thereof is remarkably large in comparison with other clay minerals. As a result, the lattice layer results in lack of positive charge and to compensate it, a cation, for example, Li⁺, Na⁺, Ca²⁺, Mg²⁺ or an organic cation, e.g., an amine salt, a quaternary ammonium salt, a phosphonium salt or a sulfonium salt is adsorbed between the lattice layers. The stratiform compound swells upon contact with water. When share is applied under such condition, the stratiform crystal lattices are easily cleaved to form a stable sol in water. The bentnite and swellable synthetic mica have strongly such tendency and are useful in the invention. In particular, swellable synthetic mica is preferably used in view of ease of availability and uniformity of quality.

The shape of the stratiform compound is tabular. The thinner the thickness or the larger the plain size as long as smoothness of coated surface and transmission of actinic radiation are not damaged, the better from the standpoint of control of diffusion. Therefore, an aspect ratio of the stratiform compound is ordinarily 20 or more, preferably 100 or more, particularly preferably 200 or more. The aspect ratio is a ratio of major axis to thickness of particle and can be determined, for example, from a projection drawing of particle by a microphotography. The larger the aspect ratio, the greater the effect obtained.

As for the particle diameter of the stratiform compound, an average diameter is ordinarily from 0.3 to 20 μm, preferably from 0.5 to 10 μm, particularly preferably from 1 to 5 μm. When the particle diameter is less than 0.3 μm, the inhibition of permeation of oxygen or moisture is insufficient and the effect of the stratiform compound can not be satisfactorily achieved. On the other hand, when it is larger than 20 μm, the dispersion stability of the particle in the coating solution is insufficient to cause a problem in that stable coating can not be performed. An average thickness of the particle is ordinarily 0.1 μm or less, preferably 0.05 μm or less, particularly preferably 0.01 μm or less. For example, with respect to the swellable synthetic mica that is the representative compound of the inorganic stratiform compounds, the thickness is approximately from 1 to 50 nm and the plain size is approximately from 1 to 20 μm.

When such an inorganic stratiform compound particle having a large aspect ratio is incorporated into the protective layer, strength of the coated layer increases and penetration of oxygen or moisture can be effectively inhibited so that the protective layer can be prevented from deterioration due to deformation, and even when the lithographic printing plate precursor is preserved for a long period of time under a high humidity condition, it is prevented from decrease in the image-forming property thereof due to the change of humidity and exhibits excellent preservation stability.

An example of common dispersing method for using the stratiform compound in the protective layer is described below.

Specifically, from 5 to 10 parts by weight of a swellable stratiform compound which is exemplified as a preferable stratiform compound is added to 100 parts by weight of water to adapt the compound to water and to be swollen, followed by dispersing using a dispersing machine. The dispersing machine used include, for example, a variety of mills conducting dispersion by directly applying mechanical power, a high-speed agitation type dispersing machine providing a large shear force and a dispersion machine providing ultrasonic energy of high intensity. Specific examples thereof include a ball mill, a sand grinder mill, a visco mill, a colloid mill, a homogenizer, a dissolver, a polytron, a homomixer, a homoblender, a keddy mill, a jet agitor, a capillary type emulsifying device, a liquid siren, an electromagnetic strain type ultrasonic generator and an emulsifying device having Polman whistle. A dispersion containing from 5 to 10% by weight of the inorganic stratiform compound thus prepared is highly viscous or gelled and exhibits extremely good preservation stability.

In the formation of a coating solution for protective layer using the dispersion, it is preferred that the dispersion is diluted with water, sufficiently stirred and then mixed with a binder solution.

The content of the inorganic stratiform compound in the protective layer is ordinarily from 5/1 to 1/100 in terms of a weight ratio of the inorganic stratiform compound to an amount of a binder used in the protective layer. When a plural kind of the inorganic stratiform compounds is used together, it is preferred that the total amount of the inorganic stratiform compounds is in the range of weight ratio described above.

Further, the protective layer may contain a known additive, for example, a plasticizer for imparting flexibility, a surfactant for improving a coating property or a fine inorganic particle for controlling a surface slipping property. The oil-sensitizing agent described with respect to the image-recording layer may also be incorporated into the protective layer.

The protective layer is coated according to a known method. The coating amount of the protective layer after drying is preferably 0.7 g/m² or less, more preferably in a range of 0 to 0.4 g/m², most preferably in a range of 0 to 0.2 g/m².

### [Plate Making Method]

Plate making of the lithographic printing plate precursor according to the invention is preferably performed by an on-press development method. The on-press development method includes a step in which the lithographic printing plate precursor is imagewise exposed and a printing step in which oily ink and an aqueous component are supplied to the exposed lithographic printing plate precursor without undergoing any development processing to perform printing, and it is characterized in that the unexposed area of the lithographic printing plate precursor is removed in the course of the printing step. The imagewise exposure may be performed on a printing machine after the lithographic printing plate precursor is mounted on the printing machine or may be separately performed using a platesetter or the like. In the latter case, the exposed lithographic printing plate precursor is mounted as it is on a printing machine without undergoing a development processing step. Then, the printing operation is initiated using the printing machine with supplying oily ink and an aqueous component and at an early stage of the printing the on-press development is carried out. Specifically, the image-recording layer in the unexposed area is removed and the hydrophilic surface of support is revealed therewith to form the non-image area. As the oily ink and aqueous component, printing ink and dampening water for conventional lithographic printing can be employed, respectively.

The on-press development method is described in more detail below.

As the light source used for the image exposure in the invention, a laser is preferable. The laser for use in the invention is not particularly restricted and includes, for example, a solid laser or semiconductor laser emitting an infrared ray having a wavelength of 760 to 1,200 nm.

With respect to the infrared ray laser, the output is preferably 100 mW or more, the exposure time per pixel is preferably within 20 microseconds, and the irradiation energy is preferably from 10 to 300 mJ/cm². With respect to the laser exposure, in order to shorten the exposure time, it is preferred to use a multibeam laser device.

The exposed lithographic printing plate precursor is mounted on a plate cylinder of a printing machine. In case of using a printing machine equipped with a laser exposure apparatus, the lithographic printing plate precursor is mounted on a plate cylinder of the printing machine and then subjected to the imagewise exposure.

When dampening water and printing ink are supplied to the imagewise exposed lithographic printing plate precursor to perform printing, in the exposed area of the image-recording layer, the image-recording layer cured by the exposure forms the printing ink receptive area having the oleophilic surface. On the other hand, in the unexposed area, the uncured image-recording layer is removed by dissolution or dispersion with the dampening water and/or printing ink supplied to reveal the hydrophilic surface in the area. As a result, the dampening water adheres on the revealed hydrophilic surface and the printing ink adheres to the exposed area of the image-recording layer, whereby printing is initiated.

While either the dampening water or printing ink may be supplied at first on the surface of lithographic printing plate precursor, it is preferred to supply the printing ink at first in view of preventing the dampening water from contamination with the component of the image-recording layer removed.

Thus, the lithographic printing plate precursor according to the invention is subjected to the on-press development on an offset printing machine and used as it is for printing a large number of sheets.

### EXAMPLES

The present invention will be described in more detail with reference to the following examples, but the invention should not be construed as being limited thereto.

### Examples 1 to 17 and Comparative Examples 1 to 4

### 1. Preparation of Lithographic Printing Plate Precursors

### (1) Preparation of Support

An aluminum plate (material: JIS A 1050) having a thickness of 0.3 mm was subjected to a degreasing treatment at 50° C. for 30 seconds using a 10% by weight aqueous sodium aluminate solution in order to remove rolling oil on the surface thereof and then grained the surface thereof using three nylon brushes embedded with bundles of nylon bristle having a diameter of 0.3 mm and an aqueous suspension (specific gravity: 1.1 g/cm³) of pumice having a median size of 25 μm, followed by thorough washing with water. The plate was subjected to etching by immersing in a 25% by weight aqueous sodium hydroxide solution of 45° C. for 9 seconds, washed with water, then immersed in a 20% by weight aqueous nitric acid solution at 60° C. for 20 seconds, and washed with water. The etching amount of the grained surface was about 3 g/m².

Then, using an alternating current of 60 Hz, an electrochemical roughening treatment was continuously carried out on the plate. The electrolytic solution used was a 1% by weight aqueous nitric acid solution (containing 0.5% by weight of aluminum ion) and the temperature of electrolytic solution was 50° C. The electrochemical roughening treatment was conducted using an alternating current source, which provides a rectangular alternating current having a trapezoidal waveform such that the time TP necessary for the current value to reach the peak from zero was 0.8 msec and the duty ratio was 1:1, and using a carbon electrode as a counter electrode. A ferrite was used as an auxiliary anode. The current density was 30 A/dm² in terms of the peak value of the electric current, and 5% of the electric current flowing from the electric source was divided to the auxiliary anode. The quantity of electricity in the nitric acid electrolysis was 175 C/dm² in terms of the quantity of electricity when the aluminum plate functioned as an anode. The plate was then washed with water by spraying.

The plate was further subjected to an electrochemical roughening treatment in the same manner as in the nitric acid electrolysis above using as an electrolytic solution, a 0.5% by weight aqueous hydrochloric acid solution (containing 0.5% by weight of aluminum ion) having temperature of 50° C. and under the condition that the quantity of electricity was 50 C/dm² in terms of the quantity of electricity when the aluminum plate functioned as an anode. The plate was then washed with water by spraying.

The plate was then subjected to an anodizing treatment using as an electrolytic solution, a 15% by weight aqueous sulfuric acid solution (containing 0.5% by weight of aluminum ion) at a current density of 15 A/dm² to form a direct current anodized film of 2.5 g/m², washed with water and dried.

Thereafter, in order to ensure the hydrophilicity of the non-image area, the plate was subjected to silicate treatment using a 2.5% by weight aqueous sodium silicate No. 3 solution at 70° C. for 12 seconds and washed with water to prepare Support (1). The adhesion amount of Si was 10 mg/m². The center line average roughness (Ra) of the support was measured using a stylus having a diameter of 2 μm and found to be 0.51 μm.

### (2) Formation of Intermediate Layer

Coating solution (1) for intermediate layer shown below was coated on Support (1) so as to have a dry coating amount of 20 mg/m² to prepare an intermediate layer. Intermediate layer (1) was formed by using Compound (1) for intermediate layer and Intermediate layer (2) was formed by using Compound (2) for intermediate layer.

<Coating solution (1) for intermediate layer>

| | |
|---|---|
| Compound for intermediate layer having | 0.18 g |
| structure shown below | |
| Hydroxyethyliminodiacetic acid | 0.10 g |
| Methanol | 55.24 g |
| Water | 6.15 g |

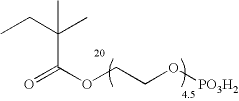

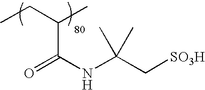

(Mw: 100,000)
Compound (1) for intermediate layer 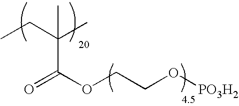 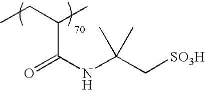 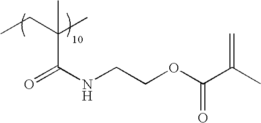
(Mw: 100,000)
Compound (2) for intermediate layer

### (3) Formation of Image-Recording Layer

A coating solution for image-recording layer shown below was coated on the support having the intermediate layer described above by a bar and dried in an oven at 70° C. for 60 seconds to form an image-recording layer having a dry coating amount of 0.60 g/m². Thus, Image-recording layers (1) to (15) were prepared as shown in Table 1 below.

<Coating solutions (1) to (11) and (13) to (15) for image-recording
layer>

| | |
|---|---|
| Aqueous dispersion of fine polymer particle | 20.0 g |
| shown in Table 1 | |
| Infrared absorbing dye (2) having structure | 0.2 g |
| shown below | |
| Radical polymerization initiator (Irgacure | 0.5 g |
| 250, produced by Ciba Specialty Chemicals, | |
| Inc.) | |
| Radical polymerizable monomer (SR-399, | 1.50 g |
| produced by Sartomer Co.) | |
| Mercapto-3-triazole | 0.2 g |
| BYK 336 (produced by BYK-Chemie GmbH) | 0.4 g |
| Klucel M (produced by Hercules Chemical Co., | 4.8 g |
| Inc.) | |
| Elvacite 4026 (produced by Ineos Acrylics | 2.5 g |
| Inc.) | |
| Polyfunctional thiol compounds (a) to (e) | Amount shown |
| | in Table 1 |
| Binder polymer (1) having structure shown | Amount shown |
| below | in Table 1 |
| Borate compound (1) having structure shown | Amount shown |
| below | in Table 1 |
| n-Propanol | 55.0 g |
| 2-Butanone | 17.0 g |

The compounds indicated using their trade names in the composition above are shown below.

### Irgacure 250:

(4-Methoxyphenyl)[4-(2-methylpropyl)phenyl]iodonium hexafluorophosphate (75% by weight propylene carbonate solution)
SR-399: Dipentaerythritol pentaacrylate
BYK 336: Modified dimethylpolysiloxane copolymer (25% by weight xylene/methoxypropyl acetate solution)
Klucel M: Hydroxypropyl cellulose (2% by weight aqueous solution)
Elvacite 4026: Highly branched polymethyl methacrylate (10% by weight 2-butanone solution)

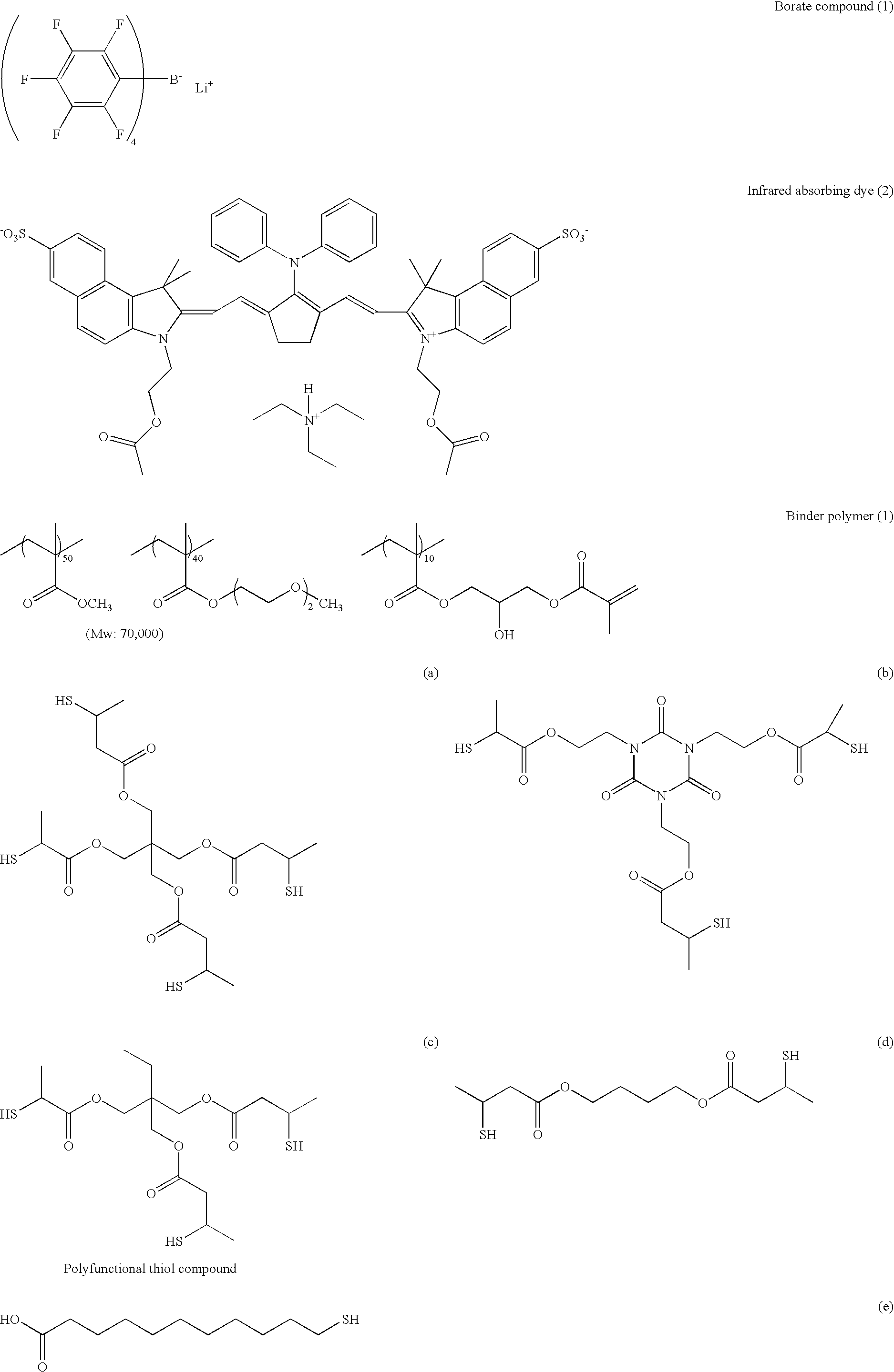

### (Preparation of AQUEOUS Dispersion of Fine Polymer Particle (A))

A stirrer, a thermometer, a dropping funnel, a nitrogen inlet tube and a reflux condenser were attached to a 1,000 ml four-neck flask and while carrying out deoxygenation by introduction of nitrogen gas, 20 g of polyethylene glycol methyl ether methacrylate (PEGMA, average number of repeating unit of ethylene glycol: 50), 200 g of distilled water and 200 g of n-propanol were charged therein and heated until the internal temperature reached 70° C. Then, a mixture of 10 g of styrene (St), g of acrylonitrile (AN) and 0.8 g of 2,2′-azobisisobutyronitrile previously prepared was dropwise added to the flask over a period of one hour. After the completion of the dropwise addition, the reaction was continued as it was for 5 hours. Then, 0.4 g of 2,2′-azobisisobutyronitrile was added and the internal temperature was raised to 80° C. Thereafter, 0.5 g of 2,2′-azobisisobutyronitrile was added over a period of 6 hours, followed by stirring for 8 hours. At the stage after reacting for 20 hours in total, the polymerization proceeded 98% or more to obtain Aqueous dispersion of fine polymer particle (A) of PEGMA/St/AN (18/9/73 in a weight ratio). The average particle size of the fine polymer particle was 0.2 μm.

The average particle size was indicated by a median diameter (50% accumulated diameter) obtained from a number average distribution. The particle size distribution was obtained by a dynamic light scattering method. As the measuring instrument, Horiba LA-910 was used.

### (Preparation of Aqueous Dispersion of Fine Polymer Particle (B))

A stirrer, a thermometer, a dropping funnel, a nitrogen inlet tube and a reflux condenser were attached to a 1,000 ml four-neck flask and while carrying out deoxygenation by introduction of nitrogen gas, 10 g of polyethylene glycol methyl ether methacrylate (PEGMA, average number of repeating unit of ethylene glycol: 50), 10 g of allyl methacrylate (AMA), 5 g of sodium dodecylsulfate, 200 g of distilled water and 200 g of n-propanol were charged therein and heated until the internal temperature reached 60° C. Then, a mixture of 10 g of allyl methacrylate (AMA), 10 g of styrene (St), 70 g of acrylonitrile (AN) and 0.8 g of 2,2′-azobisisobutyronitrile previously prepared was dropwise added to the flask over a period of one hour. After the completion of the dropwise addition, the reaction was continued as it was for 10 hours. Thereafter, 0.4 g of 2,2-azobisisobutyronitrile was added and then 0.5 g of 2,2′-azobisisobutyronitrile was added over a period of 12 hours, followed by stirring for 17 hours. At the stage after reacting for 40 hours in total, the polymerization proceeded 98% or more to obtain Aqueous dispersion of fine polymer particle (B) of PEGMA/AMA/St/AN (9/18/9/64 in a weight ratio). The average particle size of the fine polymer particle was 0.2 μm.

### (Preparation of Aqueous Dispersion of Fine Polymer Particle (C))

A stirrer, a thermometer, a dropping funnel, a nitrogen inlet tube and a reflux condenser were attached to a 1,000 ml four-neck flask and while carrying out deoxygenation by introduction of nitrogen gas, 20 g of allyl methacrylate (AMA), 5 g of sodium dodecylsulfate, 200 g of distilled water and 200 g of n-propanol were charged therein and heated until the internal temperature reached 60° C. Then, a mixture of 10 g of allyl methacrylate (AMA), 10 g of styrene (St), 80 g of acrylonitrile (AN) and 0.8 g of 2,2′-azobisisobutyronitrile previously prepared was dropwise added to the flask over a period of one hour. After the completion of the dropwise addition, the reaction was continued as it was for 10 hours. Thereafter, 0.4 g of 2,2′-azobisisobutyronitrile was added and then 0.5 g of 2,2′-azobisisobutyronitrile was added over a period of 12 hours, followed by stirring for 17 hours. At the stage after reacting for 40 hours in total, the polymerization proceeded 98% or more to obtain Aqueous dispersion of fine polymer particle (C) of AMA/St/AN (25/8/67 in a weight ratio). The average particle size of the fine polymer particle was 0.2 μm.

### <Preparation of Microgel (1)>

An oil phase component was prepared by dissolving 4.46 g of polyfunctional isocyanate having the structure shown below (produced by Mitsui Chemicals Polyurethanes, Inc., 75% ethyl acetate solution), 0.86 g of 50% ethyl acetate solution of adduct obtained by reacting one part by weight of an adduct of trimethylol propane and xylene diisocyanate (1:1 in a molar ratio) and one part by weight of terminally mono-methylated polyoxyethylene (average number of repeating unit of ethylene: 90), 1.72 g of pentaerythritol tetraacrylate (SR399E, produced by Satomer Co., Inc.) and 0.05 g of Pionin A-41C (produced by Takemoto Oil & Fat Co., Ltd., 70% methanol solution) in 4.46 g of ethyl acetate. The oil phase component and 17.30 g of water as an aqueous phase component were mixed and emulsified using a homogenizer at 10,000 rpm for 15 minutes. The resulting emulsion was heated at 40° C. for 4 hours. The microgel liquid thus-obtained was diluted using water so as to have the solid content concentration of 21.8% by weight to prepare Microgel (1). The average particle size of the microgel was 0.25 μm.

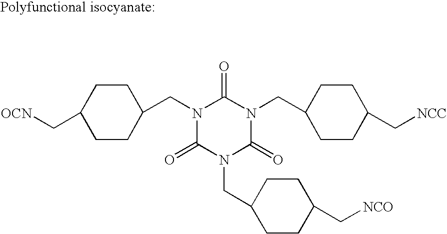

### <Coating Solution (12) for Image-Recording Layer>

Coating solution (12) for image-recording layer having the composition shown below was coated on the intermediate layer formed as described above by a bar and dried in an oven at 100° C. for 60 seconds to form Image-recording layer (12) having a dry coating amount of 1.0 g/m².

Coating solution (12) for image-recording layer was prepared by mixing Photosensitive solution (1) shown below with Microgel solution (1) shown below just before the coating, followed by stirring.

<Photosensitive solution (1)>

| | |
|---|---|
| Binder polymer (1) having structure shown | 0.24 g |
| above | |
| Infrared absorbing agent (1) having structure | 0.030 g |
| shown below | |
| Radical polymerization initiator (1) having | 0.162 g |
| structure shown below | |
| Radical polymerizable monomer | 0.192 g |
| (Tris(acryloyloxyethyl) isocyanurate (NK | |
| Ester A-9300, produced by Shin-Nakamura | |
| Chemical Co., Ltd.)) | |
| Hydrophilic low molecular weight compound | 0.062 g |
| (Tris(2-hydroxyethyl) isocyanurate) | |
| Hydrophilic low molecular weight | 0.050 g |
| compound (1) having structure shown below | |
| Oil-sensitizing agent (Phosphonium compound | 0.055 g |
| (1) having structure shown below) | |
| Oil-sensitizing agent (Benzyl dimethyl octyl | 0.018 g |
| ammonium PF₆ salt | |
| Polyfunctional thiol compound (a) | Amount shown |
| | in Table 1 |
| Fluorine-based surfactant (1) having | 0.008 g |
| structure shown below | |
| 2-Butanone | 1.091 g |
| 1-Methoxy-2-propanol | 8.609 g |

<Microgel solution (1)>

| | |
|---|---|
| Microgel (1) shown above | 2.640 g |
| Distilled water | 2.425 g |

The structures of Infrared absorbing agent (1), Radical polymerization initiator (1), Phosphonium compound (1), Hydrophilic low molecular weight compound (1) and Fluorine-based surfactant (1) are shown below.

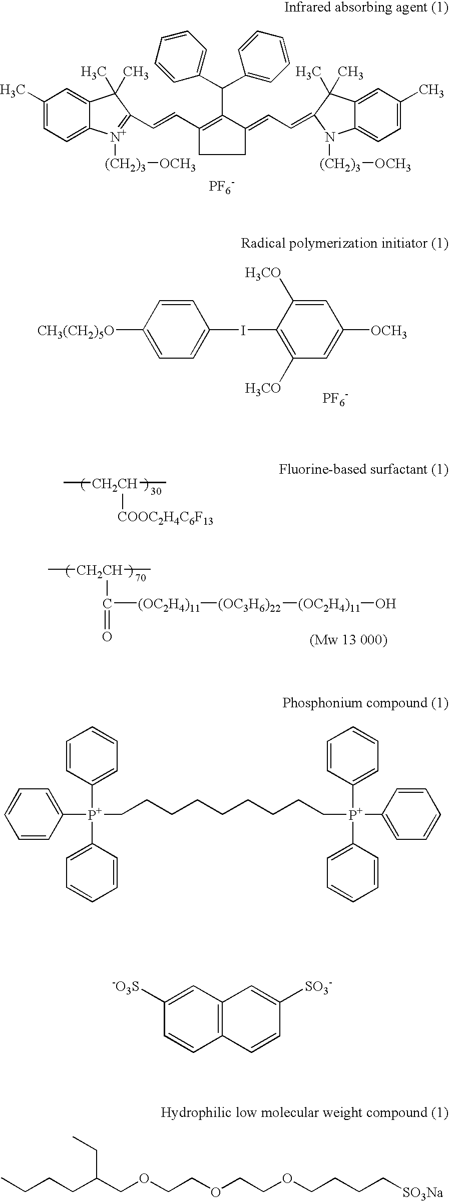

TABLE 1
Image-recording layers (1) to (15)

| | | Polyfunctional | | Amount of | Amount of |
|---|---|---|---|---|---|
| Image- | Fine | Thiol Compound | | Binder | Borate |
| recording | Polymer | | Amount | Polymer (1) | Compound (1) |
| Layer | Particle | Kind | (g) | (g) | (g) |
| (1) | (A) | a | 0.5 | None | None |
| (2) | (A) | b | 0.5 | None | None |
| (3) | (A) | c | 0.5 | None | None |
| (4) | (A) | d | 0.5 | None | None |
| (5) | (A) | a | 1.0 | None | None |
| (6) | (A) | a | 1.5 | None | None |
| (7) | (A) | a | 0.2 | None | None |
| (8) | (B) | a | 0.5 | None | None |
| (9) | Microgel | a | 0.5 | None | None |
| | (1) | | | | |
| (10) | (A) | a | 0.5 | 1.6 | None |
| (11) | (A) | a | 0.5 | None | 1.6 |
| (12) | Microgel | a | 0.08 | 0.24 | None |
| | (1) | | | | |
| (13) | (A) | — | None | None | None |
| (14) | (A) | e | 0.5 | None | None |
| (15) | (C) | a | 0.5 | None | None |

### (4) Formation of Protective Layer

Coating solution (1) for protective layer having the composition shown below was, if desired, coated on the image-recording layer formed as described above by a bar and dried in an oven at 120° C. for 60 seconds to form a protective layer having a dry coating amount of 0.2 to 1.0 g/m² as shown in Table 2, respectively.

<Coating solution (1) for protective layer>

| | |
|---|---|
| Dispersion of inorganic stratiform compound | 1.5 g |
| (1) shown below | |
| Aqueous 6% by weight solution of polyvinyl | 0.55 g |
| alcohol (CKS 50, sulfonic acid-modified, | |
| saponification degree: 99% by mole or more, | |
| polymerization degree: 300, produced by Nippon | |
| Synthetic Chemical Industry Co., Ltd.) | |
| Aqueous 6% by weight solution of polyvinyl | 0.03 g |
| alcohol (PVA-405, saponification degree: | |
| 81.5% by mole, polymerization degree: 500, | |
| produced by Kuraray Co., Ltd.) | |
| Aqueous 1% by weight solution of surfactant | 0.86 g |
| (Emalex 710, produced by Nihon Emulsion Co., | |
| Ltd.) | |
| Ion-exchanged water | 6.0 g |

### <Preparation of Dispersion of Inorganic Stratiform Compound (1)>

To 193.6 g of ion-exchanged water was added 6.4 g of synthetic mica (Somasif ME-100, produced by CO-OP Chemical Co., Ltd.) and the mixture was dispersed using a homogenizer until an average particle size (according to a laser scattering method) became 3 μm to prepare Dispersion of inorganic stratiform compound (1). The aspect ratio of the inorganic particle thus-dispersed was 100 or more.

### (5) Preparation of Lithographic Printing Plate Precursor

Lithographic printing plate precursors for Examples (17 kinds) and for Comparative Examples (4 kinds) were prepared by combining the intermediate layer, image-recording layer and protective layer described above as shown in Table 2, respectively.

### 3. Evaluation of Lithographic Printing Plate Precursor

The effective sensitivity, on-press development property and printing durability of the lithographic printing plate precursors thus-obtained were evaluated in the manner described below. The results obtained are shown in Table 2.

### (1) On-Press Development Property

Each of the lithographic printing plate precursors thus-obtained was exposed by Luxel Platesetter T-60001II equipped with an infrared semiconductor laser, produced by Fuji Film Co., Ltd. under the conditions of a rotational number of an outer surface drum of 1,000 rpm, laser output of 70% and resolution of 2,400 dpi. The exposed image contained a solid image and a 50% halftone dot chart of a 20 μm-dot FM screen.

The exposed lithographic printing plate precursor was mounted without undergoing development processing on a plate cylinder of a printing machine (Lithrone 26, produced by Komori Corp.). Using dampening water (Ecolity-2 (produced by Fuji Film Co., Ltd.)/tap water=2/98 (volume ratio)) and Values-G (N) Black Ink (produced by Dainippon Ink & Chemicals, Inc.), the dampening water and ink were supplied according to the standard automatic printing start method of Lithrone 26 to conduct on-press development and printing on 100 sheets of Tokubishi art paper (76.5 kg) at a printing speed of 10,000 sheets per hour.

A number of the printing papers required until ink density on the paper reached to the threshold state by the transfer of ink to the image area of the image-recording layer was measured as a number of papers for ink receptivity.

### (2) Effective Sensitivity

Using the same platesetter described in the evaluation for the on-press development property above, the image exposure was performed while varying the exposure amount. After performing printing of 100 sheets in the same manner as described above and confirming that a printed material free from ink stain in the non-image area was obtained, 500 sheets were continuously printed. The exposure amount for causing no unevenness in the ink density of the image area on the 600th printed material was determined to evaluate the effective sensitivity.

### (3) Printing Durability

After performing the evaluation for the on-press development property described above, the printing was continued. As the increase in a number of printing papers, the image-recording layer was gradually abraded to cause decrease in the ink density on the printing paper. A number of printing papers wherein a value obtained by measuring a halftone dot area rate of the 50% halftone dot of FM screen on the printing paper using a Gretag densitometer decreased by 5% from the value measured on the 100^{th} paper of the printing was determined to evaluate the printing durability.

TABLE 2
Examples 1 to 17 and Comparative Examples 1 to 4

| | | | Coating | | Printing | On-press |
|---|---|---|---|---|---|---|
| | | | Amount of | Effective | Durability | Development |
| | Intermediate | Image-recording | Protective | Sensitivity | (×10⁴ | Property |
| | Layer | Layer | Layer (g/m²) | (mJ/m²) | sheets) | (sheets) |
| Example 1 | 1 | 1 | None | 170 | 20 | 15 |
| Example 2 | 1 | 2 | None | 170 | 20 | 20 |
| Example 3 | 1 | 3 | None | 160 | 20 | 25 |
| Example 4 | 1 | 4 | None | 180 | 20 | 15 |
| Example 5 | 1 | 5 | None | 200 | 15 | 20 |
| Example 6 | 1 | 6 | None | 150 | 20 | 25 |
| Example 7 | 1 | 7 | None | 140 | 20 | 30 |
| Example 8 | 1 | 8 | None | 130 | 20 | 15 |
| Example 9 | 1 | 9 | None | 120 | 25 | 15 |
| Example 10 | 1 | 10 | None | 120 | 25 | 15 |
| Example 11 | 1 | 11 | None | 100 | 25 | 15 |
| Example 12 | 2 | 12 | 0.2 | 100 | 25 | 20 |
| Example 13 | 2 | 1 | None | 150 | 25 | 15 |
| Example 14 | 1 | 1 | 0.7 | 120 | 25 | 35 |
| Example 15 | 1 | 1 | 0.3 | 130 | 25 | 25 |
| Example 16 | 2 | 1 | None | 110 | 25 | 15 |
| Example 17 | 1 | 1 | 0.8 | 100 | 25 | 45 |
| Comparative | 1 | 13 | None | 300 | 15 | 20 |
| Example 1 | | | | | | |
| Comparative | 1 | 14 | None | 250 | 15 | 20 |
| Example 2 | | | | | | |
| Comparative | 1 | 15 | None | 250 | 15 | 60 |
| Example 3 | | | | | | |
| Comparative | 2 | 13 | None | 250 | 15 | 20 |
| Example 4 | | | | | | |

As is apparent from the results shown in Table 2, the lithographic printing plate precursor in which the compatibility between on-press development property, printing durability and sensitivity is achieved and the plate making method of the lithographic printing plate precursor can be provided according to the invention.

What is claimed is:

1. A lithographic printing plate precursor comprising:
an aluminum support subjected to a roughening treatment; and
an image-recording layer comprising an infrared absorbing agent, a radical polymerization initiator, a radical polymerizable monomer, a compound having two or more mercapto group-containing groups per molecule and a polymer particle containing a polyalkylene oxide segment.

2. The lithographic printing plate precursor as claimed in claim 1, wherein the mercapto group-containing group is a group represented by the following formula (a): 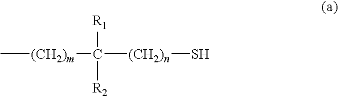
wherein R₁ and R₂ each independently represents a hydrogen atom or an alkyl group having from 1 to 10 carbon atoms, provided that at least one of R₁ and R₂ is an alkyl group, m represents an integer of from 0 to 2, and n represents 0 or 1.

3. The lithographic printing plate precursor as claimed in claim 1, wherein the mercapto group-containing group is a group represented by the following formula (b): 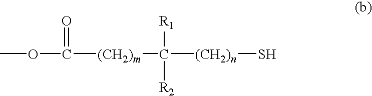
wherein R₁ and R₂ each independently represents a hydrogen atom or an alkyl group having from 1 to 10 carbon atoms, provided that at least one of R₁ and R₂ is an alkyl group, m represents an integer of from 0 to 2, and n represents 0 or 1.

4. The lithographic printing plate precursor as claimed in claim 1, wherein the polymer particle is a particle comprising a repeating unit having a cyano group.

5. The lithographic printing plate precursor as claimed in claim 1, wherein the polymer particle comprises an ethylenically unsaturated bond.

6. The lithographic printing plate precursor as claimed in claim 1, wherein the image-recording layer further comprises a binder polymer.

7. The lithographic printing plate precursor as claimed in claim 6, wherein the binder polymer comprises a polyalkylene oxide segment.

8. The lithographic printing plate precursor as claimed in claim 6, wherein the binder polymer comprises an ethylenically unsaturated bond.

9. The lithographic printing plate precursor as claimed in claim 1, which further comprises an intermediate layer containing a polymer having both a support-adsorbing group and a polymerizable group between the support and the image-recording layer.

10. The lithographic printing plate precursor as claimed in claim 1, which has a protective layer having a coating amount of 0.7 g/m² or less so that the aluminum support, the image-recording layer and the protective layer are provided in this order, or which does not have a protective layer.

11. The lithographic printing plate precursor as claimed in claim 10, wherein the protective layer comprises an inorganic stratiform compound.

12. The lithographic printing plate precursor as claimed in claim 1, wherein the image-recording layer further comprises a borate compound.

13. The lithographic printing plate precursor as claimed in claim 12, wherein the borate compound is a compound having a tetraarylborate structure.

14. A plate making method of the lithographic printing plate precursor as claimed in claim 1, the method comprising:
imagewise exposing the lithographic printing plate precursor; and
removing an unexposed area by supplying oily ink and dampening water to the exposed lithographic printing plate precursor provided on a printing machine to prepare a lithographic printing plate,
wherein a development processing is not conducted between the imagewise exposing and the removing.
